(19) United States
(12) Patent Application Publication
(10) Pub. No.: US 2012/0024335 A1
(43) Pub. Date: Feb. 2, 2012

(54) MULTI-LAYERED THERMOELECTRIC DEVICE AND METHOD OF MANUFACTURING THE SAME

(75) Inventors: Sung Ho LEE, Gyeonggi-do (KR); Yong Suk Kim, Gyeonggi-do (KR); Young Soo Oh, Gyeonngi-do (KR); Tae Kon Koo, Seoul (KR); Sung Kwon Wi, Seoul (KR)

(73) Assignee: SAMSUNG ELECTRO-MECHANICS CO., LTD.

(21) Appl. No.: 12/947,037

(22) Filed: Nov. 16, 2010

(30) Foreign Application Priority Data
Jul. 29, 2010 (KR) 10-2010-0073589

(51) Int. Cl. H01L 35/16; H01L 21/18; H01L 35/20

(52) U.S. Cl. 136/238; 136/240; 438/54; 136/201; 257/E21.087

(57) ABSTRACT

The present invention provides a multi-layered thermoelectric device and a method of manufacturing the same. The method for manufacturing a multi-layered thermoelectric device includes the steps of: forming a P-type semiconductor and an N-type semiconductor in a sheet type by mixing thermoelectric semiconductor materials at a preset component ratio; cutting the sheets according to a preset specification of the thermoelectric device; stacking sheets which are made by mixing the thermoelectric semiconductor materials at a preset component ratio and are cut into the same size for each of them; and forming a final thermoelectric device by compressing the stacked sheets. By using the method, scattering phenomenon due to a short wavelength of phonon occurs at a boundary of each layer, which results in active scattering of phonon. Therefore, it is possible to expect an effect of improving a thermoelectric figure of merit of a thermoelectric device.

### CROSS-REFERENCE TO RELATED APPLICATIONS

This application claims the benefit under 35 U.S.C. Section [120, 119, 119(e)] of Korean Patent Application Serial No. 10-2010-0073589, entitled “Multi-Layered Thermoelectric Device And Method Of Manufacturing The Same” filed on Jul. 29, 2010, which is hereby incorporated by reference in its entirety into this application.

### BACKGROUND OF THE INVENTION

1. Field of the Invention

The present invention relates to a multi-layered thermoelectric device and a method of manufacturing the same; and, more particularly, to a multi-layered thermoelectric device having a structure where thermoelectric semiconductors with the same material are stacked in sheet shapes to thereby improve a thermoelectric figure of merit thereof, and a method for manufacturing the same.

2. Description of the Related Art

A rapidly increased use in fossil energies causes global warming and energy exhaustion. In order to solve these problem, there have recently been conducted many studies on the thermoelectric module that can effectively use energies.

In general, a thermoelectric module may be used as a power generator employing a seebeck effect and a cooling system employing a peltier effect. Herein, the seebeck effect refers to a principle where an electromotive force is generated when temperature differences are given to each end of a thermoelectric device, and the peltier effect refers to a principle where heat is released at one end and absorbed at the other end thereof when a direct current is applied to a thermoelectric device.

Herein, thermoelectric modules may include upper and lower electrodes, and a thermoelectric device interposed between the upper and lower electrodes. Herein, a substrate for supporting the thermoelectric module is disposed on an upper surface of each of the upper and lower electrodes. At this time, as the substrate, an alumina substrate with a superior electrical insulating property has been mainly used.

Meanwhile, in the prior art, thermoelectric material has been mainly manufactured by mixing metal raw materials at a predetermined composition ratio and using a mechanical alloying. That is, in a bulk-shaped thermoelectric device, by using basic processes like initial solution, crushing, and sintering, dopants are added thereto to thereby manufacture a P-type semiconductor and an N-type semiconductor.

Also, those skilled in the art concentrates on developments a technology where thermoelectric particles are micronized and sintering density is improved, so as to increase thermoelectric performance.

In a thin-film process, there have been a lot of efforts to improve thermoelectric figure of merit by using a super-lattice or a thermoelectric thin film whose dimension is lowered through various deposition techniques.

### SUMMARY OF THE INVENTION

The present invention has been proposed in order to overcome the above-described problems and it is, therefore, an object of the present invention to provide a multi-layered thermoelectric device for improving a thermoelectric figure of merit thereof and a method for manufacturing the same.

In accordance with one aspect of the present invention to achieve the object, there is provided a method for manufacturing a multi-layered thermoelectric device including the steps of: forming a P-type semiconductor and an N-type semiconductor in a sheet type by mixing thermoelectric semiconductor materials at a preset component ratio; cutting the sheets according to a preset specification of the thermoelectric device; stacking sheets which are made by mixing the thermoelectric semiconductor materials at a preset component ratio and are cut into the same size for each of them; and forming a final thermoelectric device by compressing the stacked sheets.

Also, in the step of stacking the sheets with the same material as one another, the sheets are formed of the same material and cut into the same size for each of them.

In addition, preferably, each of the sheets is formed to have a thickness in a range of 100 μm to 1000 μm by being subjected to a thick-film process.

Preferably, the final thermoelectric device has a structure where a plurality of sheets are stacked to be parallel to its bottom surface.

Preferably, the thermoelectric semiconductor material is formed by a mixture of Bi and Te.

In addition, preferably, the thermoelectric semiconductor material is formed of ZnxSby, wherein, x/y has a value of 0.5 to 1.5.

Preferably, the thermoelectric semiconductor material is formed of CoxSby, wherein, x/y has a value of 0.1 to 1.0.

In accordance with another aspect of the present invention to achieve the object, there is provided a multi-layered thermoelectric device being formed of the same thermoelectric semiconductor material and having a structure where a plurality of sheets cut into the same size are stacked, wherein the thermoelectric semiconductor material is a P-type thermoelectric semiconductor material or an N-type thermoelectric semiconductor material.

Preferably, each of the plurality of sheets is formed to have a thickness in a range of 100 μm to 1000 μm by being subjected to a thick-film process.

Preferably, the thermoelectric device has a structure where a plurality of sheets are stacked to be parallel to its bottom surface.

Preferably, the thermoelectric semiconductor material is formed by a mixture of Bi and Te.

Preferably, the thermoelectric semiconductor material is formed of ZnxSby, wherein, x/y has a value of 0.5 to 1.5.

Preferably, the thermoelectric semiconductor material is formed of CoxSby, wherein, x/y has a value of 0.1 to 1.0.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view showing a substrate having a multi-layered thermoelectric device of the present invention mounted thereon; and

FIGS. 2 to 6 are process diagrams for successively explaining a method for manufacturing a multi-layered thermoelectric device in accordance with an embodiment of the present invention, respectively.

### DETAILED DESCRIPTION OF THE PREFERABLE EMBODIMENTS

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements. Further, the dimensions of layers and regions are exaggerated for clarity of illustration.

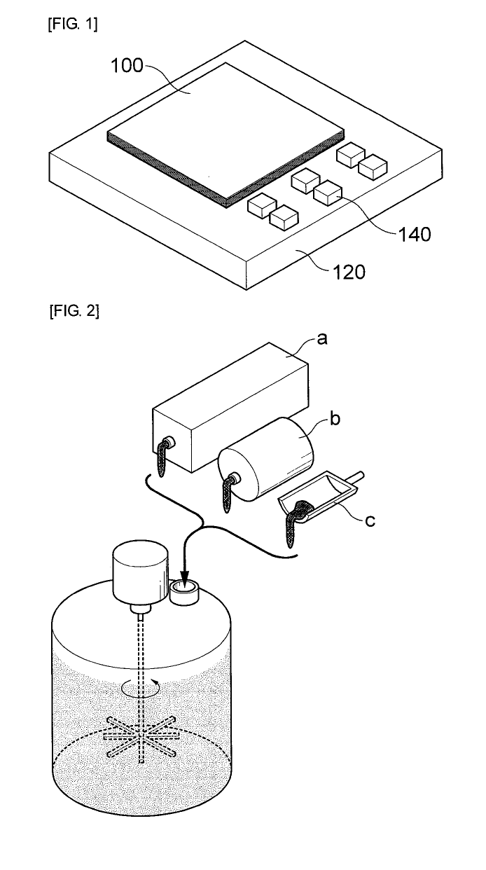

FIG. 1 is a view showing a substrate with a multi-layered thermoelectric device mounted thereon.

As shown in FIG. 1, the multi-layered thermoelectric device 100 has a structure made by stacking a plurality of sheets which are formed of the same thermoelectric semiconductor material and cut into the same size.

The above-described structure may be expected to provide an effect that bulk/thick-films with the same material are manufactured to have multiple layers at a thin thickness, so as to enhance the performance of the multi-layered thermoelectric device 100, so that it is possible to restrict the movement of phonon while maintaining transfer of electrons as in an original state.

Also, since the multi-layered thermoelectric device 100 reflects a process for stacking a plurality of sheets formed of the same material, it is possible to simplify procedures required for the process. This means that the multi-layered thermoelectric device 100 of the present invention has sheets all of which are made of the same material as one another.

Herein, the thermoelectric semiconductor material may include a P-type semiconductor material or an N-type semiconductor material. Also, each of the sheets may be formed to have a thickness in a range of 100 μm to 1000 μm by being subjected to a thick-film process.

In addition, the thermoelectric semiconductor material may be made by mixing Bi and Te.

Also, the thermoelectric semiconductor material may be formed of ZnxSby, (where, x/y may be adjusted to have a value of 0.5 to 1.5).

Meanwhile, the thermoelectric semiconductor material may be formed of CoxSby, (where x/y may be adjusted to have a value of 0.1 to 1.0).

The multi-layered thermoelectric device 100 may have a structure where a plurality of sheets are stacked in a parallel relation with respect to its bottom surface.

As shown in FIG. 1, the multi-layered thermoelectric device 100 and other electronic components 130 may be mounted together on a substrate 120.

Meanwhile, a thermoelectric figure of merit of the conventional thermoelectric device is defined by equation (1) below.

$$zT = \frac{{α}^{2} σ}{k} T \qquad ( 1 )$$

In equation (1), zT denotes a thermoelectric figure of merit, a denotes a seebeck coefficient, a denotes an electrical conductivity, k denotes a thermal conductivity, and T denotes a temperature.

As expressed in equation (1), the thermal conductivity and the electric conductivity have a correlation between them. Also, electrons functions to transfer heat together with electricity, and phonon servers as a medium for transferring heat.

As expressed in equation (1), since the electrical conductivity and the thermal conductivity have an inversely proportional relation between them, electrons should be well transferred from one end to the opposed end of the thermoelectric device in order to improve zT (i.e. a thermoelectric figure of merit), which requires scattering of phonons.

The wavelength of the phonon is 1 nm, and the wavelength of the electron is in a range of 10 to 100 nm.

Since the multi-layered thermoelectric device 100 disclosed in the present invention has a structure where a plurality of sheets with the same material as one another are stacked, scattering phenomenon resulting from a short wavelength of phonon occurs at a boundary between respective layers. This results in improvement of a thermoelectric figure of merit zT.

FIGS. 2 to 6 are process diagrams for successively explaining the method for manufacturing the multi-layered thermoelectric device in accordance with an embodiment of the present invention, respectively.

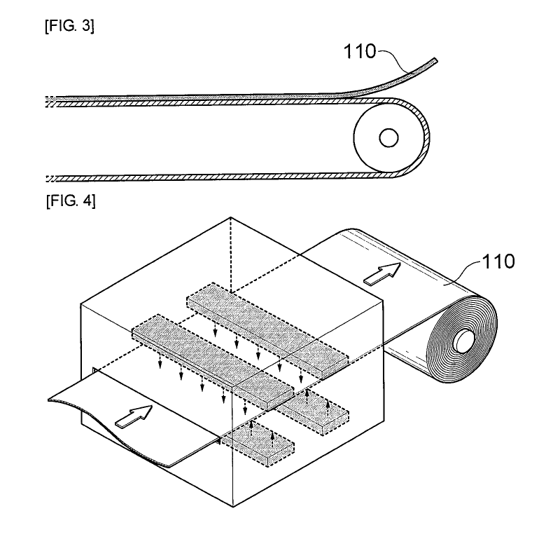

First, the multi-layered thermoelectric device 100 according to the present invention may be formed by the following processes. First, thermoelectric semiconductor materials may be mixed together at a preset composition ratio to form a P-type semiconductor or an N-type semiconductor, as shown in FIG. 2, and then the resultant P-type semiconductor or the resultant N-type semiconductor may be formed in a sheet type, as shown in FIG. 3. For example, as shown in FIG. 2, a solvent (a), a binder (b), a powder (c) may be mixed together. Herein, the thermoelectric semiconductor material may be made by a mixture of Bi and Te.

Also, the thermoelectric semiconductor material is formed of ZnxSby (where, x/y may have a value of 0.5 to 1.5). In addition, the thermoelectric semiconductor material is formed of CoxSby (where x/y may have a value of 0.1 to 1.0).

Also, the sheet 110 for the multi-layered thermoelectric device 100 may be formed through well-known various techniques.

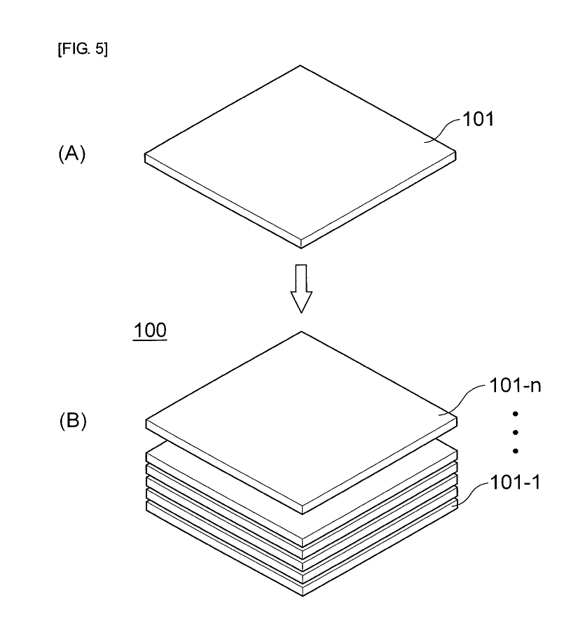

Thereafter, as shown in FIG. 4, the sheet 110 may be dried through a heat-ray technology, but the dry method is not limited thereto.

Thereafter, although not shown in the accompanying drawings, the sheet 110 may be cut according to a preset specification of a thermoelectric device.

Thereafter, as shown in FIGS. 5A and 5B, sheets 101-1 to 101-n made by mixing the same thermoelectric semiconductor material at a preset composition ratio may be stacked in multiple layers. Herein, in the step of stacking the sheets, the stacked sheets stacked may be formed of the same material for each of them and may be cut into the same size.

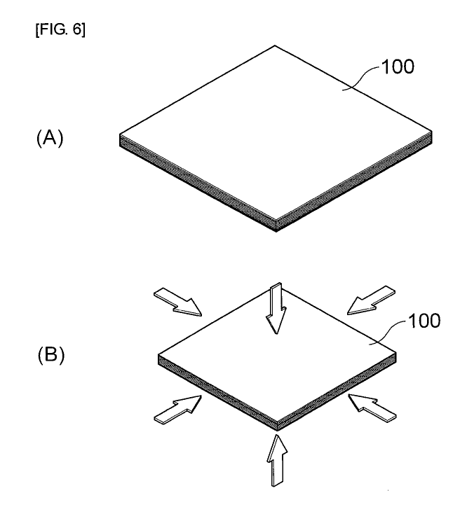

As shown in FIGS. 6A and 6B, the stacked sheets are pressed and attached to finally form the multi-layered thermoelectric device 100.

Herein, each of the stacked sheets may be formed to have the thickness in a range of 100 μm to 1000 μm by being subjected to a thick-film process.

Meanwhile, the finally-formed thermoelectric device may have a structure where a plurality of sheets are stacked to be parallel to the bottom surface, as shown in FIGS. 5B and 6A.

In a multi-layered thermoelectric device and a method for manufacturing the same according to the present invention, it is possible to expect an effect of improving a thermoelectric figure of merit thereof because of active phonon's scattering at each layer due to a short wavelength of phonon.

Also, in the present invention, sheets are stacked by using a ceramic process, so that it is possible to implement mass-production of a thermoelectric semiconductor, in comparison with super-lattice between different kinds used in the conventional thin-film process, which results in a decrease in manufacturing's cost.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A method of manufacturing a multi-layered thermoelectric device comprising:
forming a P-type semiconductor and an N-type semiconductor in a sheet type by mixing thermoelectric semiconductor materials at a preset component ratio;
cutting the sheets according to a preset specification of the thermoelectric device;
stacking sheets which are made by mixing the thermoelectric semiconductor materials at a preset component ratio and are cut into the same size for each of them; and
forming a final thermoelectric device by compressing the stacked sheets.

2. The method of manufacturing a multi-layered thermoelectric device according to claim 1, wherein, in stacking the sheets with the same material as one another, the sheets are formed of the same material and cut into the same size for each of them.

3. The method of claim 2, wherein each of the sheets is formed to have a thickness in a range of 100 μm to 1000 μm by being subjected to a thick-film process.

4. The method of claim 3, wherein the final thermoelectric device has a structure where a plurality of sheets are stacked to be parallel to its bottom surface.

5. The method of claim 4, wherein the thermoelectric semiconductor material is formed by a mixture of Bi and Te.

6. The method of claim 4, wherein the thermoelectric semiconductor material is formed of ZnxSby,
wherein, x/y has a value of 0.5 to 1.5.

7. The method of claim 4, wherein the thermoelectric semiconductor material is formed of CoxSby,
wherein, x/y has a value of 0.1 to 1.0.

8. A multi-layered thermoelectric device being formed of the same thermoelectric semiconductor material and having a structure where a plurality of sheets cut into the same size are stacked, wherein the thermoelectric semiconductor material is a P-type thermoelectric semiconductor material or an N-type thermoelectric semiconductor material.

9. The multi-layered thermoelectric device according to claim 8, wherein each of the plurality of sheets is formed to have a thickness in a range of 100 μm to 1000 μm by being subjected to a thick-film process.

10. The multi-layered thermoelectric device of claim 9, wherein the thermoelectric device has a structure where a plurality of sheets are stacked to be parallel to its bottom surface.

11. The multi-layered thermoelectric device of claim 10, wherein the thermoelectric semiconductor material is formed by a mixture of Bi and Te.

12. The multi-layered thermoelectric device of claim 10, wherein the thermoelectric semiconductor material is formed of ZnxSby,
wherein, x/y has a value of 0.5 to 1.5.

13. The multi-layered thermoelectric device of claim 10, wherein the thermoelectric semiconductor material is formed of CoxSby,
wherein, x/y has a value of 0.1 to 1.0.
